(19) United States
(12) Patent Application Publication
(10) Pub. No.: US 2015/0228665 A1
(43) Pub. Date: Aug. 13, 2015

(54) DISPLAY DEVICE AND METHOD OF MANUFACTURING THE SAME

(71) Applicant: SAMSUNG DISPLAY CO., LTD., Yongin-si (KR)

(72) Inventors: Bong- Yeon KIM, Seoul (KR); Seung-Bo SHIM, Asan-si (KR); Dong-Eon LEE, Seoul (KR); Jun-hyuk WOO, Yongin-si (KR)

(21) Appl. No.: 14/509,774

(22) Filed: Oct. 8, 2014

(30) Foreign Application Priority Data
Feb. 11, 2014 (KR) 10-2014-0015334

(51) Int. Cl. H01L 27/12; G03F 7/30; G03F 1/26; H01L 29/786; H01L 21/033

(52) U.S. Cl. CPC H01L 27/124; H01L 27/1288; H01L 29/78669; H01L 29/7869; H01L 21/0331; G03F 1/26; G03F 7/30

(57) ABSTRACT

A display device includes a substrate, a gate line and a data line on the substrate, a thin film transistor on the substrate, being connected to the gate line and the data line, a pixel electrode connected to the thin film transistor, and an insulating layer on the substrate, wherein the insulating layer has a contact hole extending therethrough and the contact hole has a relatively steep sidewall including a sidewall portion with a sidewall taper angle of about 60° to about 90°.

### CROSS-REFERENCE TO RELATED APPLICATION

This application claims priority to and the benefit of Korean Patent Application No. 10-2014-0015334, filed on Feb. 11, 2014, with the Korean Intellectual Property Office, the disclosure of which application is incorporated herein in its entirety by reference.

### BACKGROUND

1. Field

The present disclosure of invention relates to a display device having a contact hole where the contact hole is formed using a lithographic exposure mask that comprises a light blocking unit surrounding both of a light transmitting unit, and a transflective unit.

2. Description of Related Technology

In general, flat or otherwise thin panel displays (FPDs) such as liquid crystal displays and organic light emitting diode displays include opposed electric field generating electrodes and an electro-optically active layer disposed to be affected by correspondingly generated electric fields. In the case of the liquid crystal display, a liquid crystal layer is included as the electro-optically active layer, and in the case of the organic light emitting diode display, an organic light emitting layer is included as the electro-optically active layer.

One of the opposed electric field generating electrodes is generally connected to a switching element so that it receives an electrical signal on a selective basis. The electro-optically active layer is affected by the received electrical signal such that it forms a corresponding optical signal as part of a formed and to be displayed image.

According to one trend in the mass production of large area and highly integrated display devices, phase shift masks are used to form fine lithographic patterns. An aspect of phase shift masks is that they can be structured to allow graded amounts (e.g., small amounts) of light as well as bright light to be transmitted therethrough as compared to binary masks which are either all on or all off in terms of transmitted through light rays. On the other hand, to produce a finely patterned area it is often required to be intensively exposed to light when using the phase shift masks and positive development types of photoreactive layers (photoresists). The phase shift masks tend to have an image log slope (ILS) value relating to high resolution, and these can be adjusted to increase resolution but at the same time the thickness of adjacent material that is not supposed to be etched away tends to disadvantageously decrease. Therefore, while an inclined sidewall surface of a contact hole formed by the phase shift mask approach advantageously has a high sidewall gradient, the thickness of material adjacent to the hole needs to be increased so that corresponding process margins can be improved.

More specifically, in the case where the phase shift mask is used, the total amount of light transmitted through the phase shift mask to a positive development type, photoreactive resist or other such layer is increased relative to a maximum intensity of light (Imax) used for forming a through hole (the contact hole) such that partial back-etching occurs (reduction of thickness as opposed to a through hole) such that pattern defects may occur, for example an insulating layer adjacent to a contact hole may undesirably protrude above a desired plane, and/or an insulating layer where a contact hole is not intended to be formed may nonetheless be partly etched back to thus undesirably reduce insulation thickness.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding invention dates of subject matter disclosed herein.

### SUMMARY

The present disclosure of invention is directed to a display device and to a mass production method of manufacturing the same to have through holes (e.g., drain contact holes) with relatively steep sidewalls. More specifically, the present disclosure is directed to a display device in which a contact hole is formed using a lithographic exposure mask for use in positive pattern development where the mask includes a first light blocking unit surrounding a light transmitting unit, a transflective unit surrounding the first light blocking unit and a second light blocking unit surrounding the transflective unit so that both resolution and process margin can be improved by appropriate adjustments to respective widths of the first light blocking unit and of the transflective unit.

According to an embodiment, a display device includes: a light-passing substrate; a gate line and a data line disposed on the substrate; a thin film transistor (TFT) also disposed on the substrate, the TFT being connected to the gate line and to the data line; a pixel electrode connected to the thin film transistor; and an insulating layer disposed on the substrate and covering one or more electrically conductive elements of the display device, wherein the insulating layer has a contact hole extending therethrough and the contact hole has a sidewall with a relatively steep taper angle of about 60° to about 90° in the contact hole.

The insulating layer may be configured to cover at least one of a semiconductive layer, a drain electrode, a gate line, a data line, and a pad electrode.

Any one or more of a semiconductie layer, a drain electrode, a gate line, a data line, and a pad electrode of the display device may be exposed by a respective contact hole having the said relatively steep taper angle of about 60° to about 90°.

According to an embodiment, an exposure mask includes: a light transmitting unit; a first light blocking unit surrounding the light transmitting unit; a transflective unit surrounding the first light blocking unit; and a second light blocking unit surrounding the transflective unit.

The first light blocking unit and the transflective unit may have different widths from each other.

The light transmitting unit may have a circular or polygonal shape.

The light transmitting unit may be a pattern configured to form a contact hole.

The width ratio of the first light blocking unit to the transflective unit may be 1:0.9 to 1:2.25.

The first light blocking unit may have a width of about 0.1 μm to about 1 μm.

The transflective unit may have a width of about 0.1 μm to about 5 μm.

According to an embodiment, a method for manufacturing a display device includes: forming an insulating layer on a light-passing substrate; patterning the insulating layer by exposing a corresponding, positive development photoreactive layer to a development light using an exposure mask; and forming a contact hole by using the developed photoreactive layer as an etch mask, wherein the exposure mask includes: a light transmitting unit; a first light blocking unit surrounding the light transmitting unit; a transflective unit surrounding the first light blocking unit; and a second light blocking unit surrounding the transflective unit.

The first light blocking unit and the transflective unit may have different widths from each other.

The light transmitting unit, the first light blocking unit, and the transflective unit may be formed on an area where the contact hole is formed.

The insulating layer may have a taper angle of about 60° to about 90° in the contact hole.

The light transmitting unit may have a circular or polygonal shape.

The light transmitting unit may be a pattern configured to form a contact hole.

The width ratio of the first light blocking unit to the transflective unit may be 1:0.9 to 1:2.25.

The first light blocking unit may have a width of about 0.1 μm to about 1 μm.

The transflective unit may have a width of about 0.1 μm to about 5 μm.

According to embodiments of the present invention, a display device is capable of improving resolution by increasing image log slope (ILS), increasing process margin, preventing an insulating layer having a contact hole from being excessively etched, preventing an insulating layer in the vicinity of an area where the contact hole is formed from protruding so as to be flat, and forming a fine contact hole by increasing a gradient of an inclined surface of the insulating layer in the contact hole.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure of invention will be more clearly understood from the following detailed description taken in conjunction with the accompanying drawings, in which:

FIG. 1 is a schematic plan view showing a display device structured in accordance with the present disclosure of invention;

FIG. 2 provides comparative cross-sectional views for comparing intensity of light passed through different kinds of masks, more specifically, phase shift masks and binary masks, and the corresponding image log slopes (ILS) resulting therefrom;

FIG. 3 provides comparative cross-sectional views showing a display area and the corresponding, all-binary or all-phase shift mask for forming the structure taken along line A-A′ of FIG. 1;

FIG. 4 provides comparative plan views showing part-binary/part-phase shift exposure mask configurations according to an embodiment of the present disclosure;

FIG. 5 is cross-sectional views of a display area and an exposure mask, taken along line A-A′ of FIG. 1; and

FIGS. 6A to 6E are graphs showing image log slope curves (ILS) whose respective shapes depend on corresponding frame widths of a first light blocking unit and a transflective unit respectively formed on each of the ILS characterized exposure masks.

### DETAILED DESCRIPTION

Advantages and features of structures formed in accordance with the present disclosure of invention and methods for achieving them will be made clear from embodiments described below in more detail with reference to the accompanying drawings. The present teachings may, however, be embodied in many different forms and should not be construed as being limited to the specific embodiments set forth herein. Rather, these embodiments are provided so that this disclosure will be thorough and complete, and will fully convey the scope of the present teachings to those skilled in the pertinent art. Like reference numerals refer to like elements throughout the specification.

The spatially relative terms “below”, “beneath”, “lower”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

The terminology used herein is for the purpose of describing particular embodiments only and is not construed as limiting the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of mentioned component, step, operation and/or element, but do not exclude the presence or addition of one or more other components, steps, operations and/or elements.

Unless otherwise defined, all terms used herein (including technical and scientific terms) have the same meaning as commonly understood by those skilled in the art to which this disclosure of invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

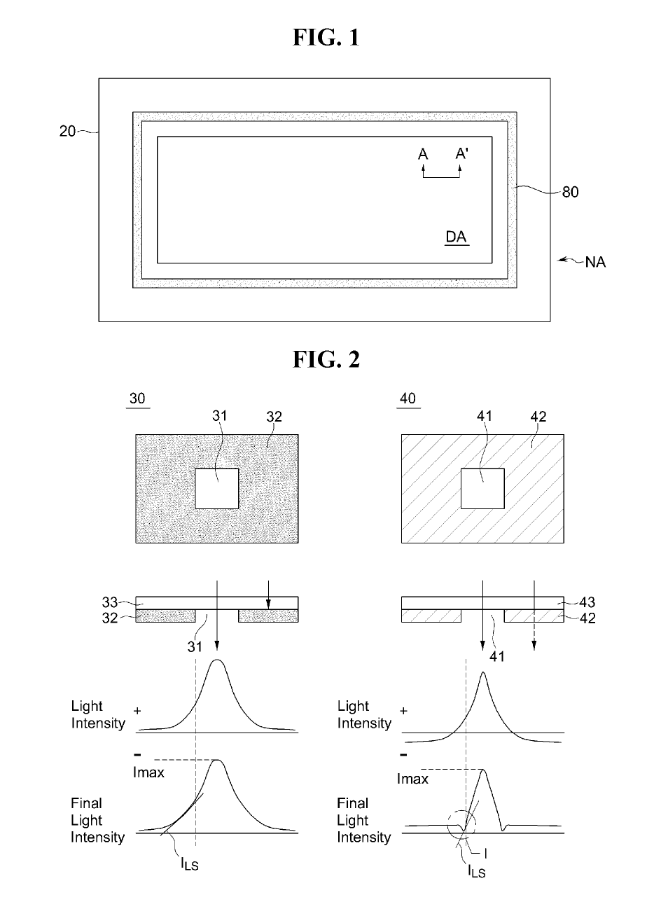

Hereinafter, the comparative cases where respective contact holes are formed using all-binary masks and all-phase shift masks will be described in detail with reference to FIGS. 1 to 3.

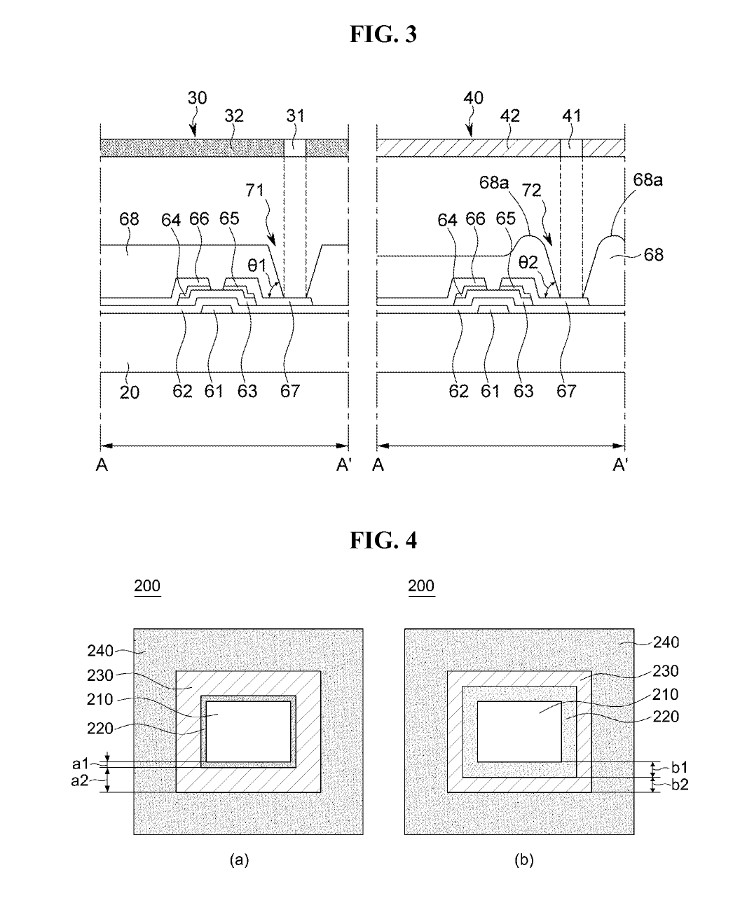

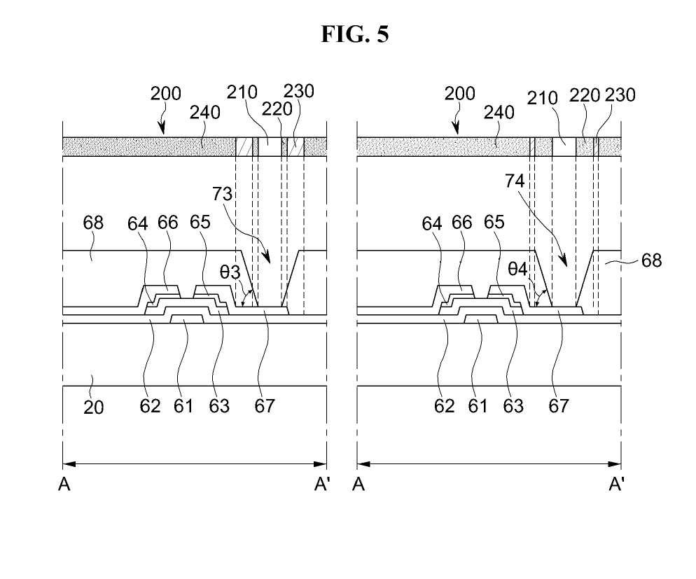

FIG. 1 is a schematic plan view showing a display device which may be formed either according to the present disclosure of invention or conventionally by use of only all-binary masks or only all-phase shift masks. FIG. 2 shows comparative cross-sectional views for comparing intensity of light passing through respectively through an all-binary mask (on the left) and an all-phase shift masks (on the right) and the corresponding image log slope curves (ILS). FIG. 3 shows comparative cross-sectional views showing a display area and a mask, as if taken along line A-A′ of FIG. 1 in the case where an all-binary mask (on the left) is used and in the case where an all-phase shift mask (on the right) is used.

Referring to FIG. 1, the display device according to an embodiment in accordance with the present disclosure of invention includes a light-passing substrate 20 which is partitioned into two areas, namely an image displaying area DA and a non-displaying area NA. A plurality of pixel units are disposed in the display area DA of the substrate 20 and structured so as to display an electronically-defined image. One or more contact pad electrodes (not shown) may be disposed in the non-display area NA for providing interfacing with external electronic circuits (not shown). The pad electrodes need not be all in the entire non-display area NA. Some or all of the pad electrodes may be provided outside the non-display area NA.

A sealing member 80 is disposed in the non-display area NA so as to allow the pixel-units hosting substrate 20 and an opposed light-passing substrate (not shown) to be sealingly bonded to each other so as to formed a sealed volume in which the electro-optically active layer (e.g., liquid crystals) may be containerized. The sealing member 80 may include a thermosetting resin such as an epoxy resin.

Referring to FIG. 2, maximum intensity of light (Imax) passed through a respective mask and an image log slope (ILS) of contrast relative to the peak intensity (Imax) passed through an opening of the lithographic exposure mask (for example based on destructive light wave interference in the case of phase shift masks) can be predicted for the respective cases of using an all-binary mask (left side) and of using an all-phase shift type of mask (right side).

As used herein, the maximum intensity of light (Imax) refers to the highest value of light intensities for various wavelengths as passed through an essentially transparent opening of a patterned mask. Image log slope (ILS) refers to a slope of normalized light intensity passed through to a photoreactive layer (e.g., positive development photoresist layer) and is used to determine patterning quality based on the slope of the resulting, normalized light intensity in the photoreactive layer (PR layer). As will be appreciated from what follows, the more intense the light is that is supplied to the positive development type photoreactive layer, the deeper is the depth of etching and the Imax region indicates where the depth of etching is equal to or greater than the thickness of insulating material such that a through hole (contact hole) is desirably formed there. At the same time, the ILS is a slope of a hypothetical tangent line taken at a point on the light intensity curve. The ILS may be used to check on pattern vulnerability to formation of undesirably thin insulation features. As an ILS value decreases, light at the corresponding point may become more diffused, and as the ILS value increases, light at the corresponding point of the finely patterned area may become more concentrated and more intense so as to more effectively interact with the photoreactive layer (PR layer) and result in deeper etching. Thus, as the ILS value increases, resolution of a pattern formed within the display device may become more improved, but only in the case where the light is concentrated in a desired to-be-etched-through area as opposed to being undesirably increased in adjacent spots such that process margins are degraded.

When an all-binary mask such as the one shown at 30 in FIG. 2 is provided, it has a completely light blocking feature 32 patterned therein so as to completely block passage of light therethrough and it has a full light transmitting feature (e.g., opening 31) in the center. The all-binary mask may have a quartz substrate 33 on which the light blocking feature 32 is disposed. Such a quartz substrate 33 may be used to pass through UV and near UV wavelengths. By contrast, when an all-phase shift mask such as the one shown at 40 in FIG. 2 is provided, it has a phase-shifting and intensity-reducing feature 42 patterned therein (also referred to as a transflective unit 42) which causes a phase shift of passed through light so as to induce destructive interference with further light passed through a light transmitting feature (e.g., opening 41—also referred to as a light transmitting unit 41) where the all-phase shift mask may have a quartz substrate 43 on which the transflective feature 42 is disposed. The quartz substrate 43 may be used in conjunction with near UV and near UV wavelengths.

In the binary mask 30, intensity of light passing through the light transmitting unit 31 is concentrated in an area to which the light transmitting unit 31 is directed towards. However, the binary mask 30 has difficulties in adjusting the light intensity to be suitable for defining high resolution line width boundaries of a fine pattern because the light intensity has gradual image log slope (ILS) as depicted in the graphs of FIG. 2.

By contrast, in the all-phase shift mask 40, light is transmitted through the light transmitting unit 41 and also through the transflective unit 42. An exposure dose of light transmitted through the transflective unit 42 is about 1% to about 10% of the total exposure dose of light irradiated onto the mask. As illustrated in FIG. 2, destructive interference occurs where the outer boundary of the opening 41 meets with the inner boundary of the transflective unit 42 so that, due to a phase difference of 180 degrees between the light transmitted through the light transmitting unit 41 and the light transmitted through the transflective unit 42 the destructive interference occurs. Light intensity of an area adjacent to the light transmitting unit 41 and the transflective unit 42 is lowest in an area marked with circle I in the bottom right graph of FIG. 2 by the destructive interference. Further, the image log slope (ILS) increases in the case of using the phase shift mask 40 compared to the binary mask 30. Therefore, the phase shift mask 40 can better concentrate light in a finer pattern area when compared to the binary mask 30.

Although the phase shift mask 40 can concentrate light in a small area, the total exposure dose of light transmitted through the phase shift mask 40 is increased such that adjacent material, adjacent to the contact hole is undesirably removed and thus designers must carefully adjust the exposure dose of light supplied by the exposure apparatus so that light to the adjacent areas is not increased too much. In other words, in comparative terms, the maximum light intensity is lowered in the phase shift mask 40 as compared to the binary mask 30, and a pattern may be incompletely formed on a display substrate when the phase shift mask 40 is used.

More specifically and still referring to FIG. 3, the side-by-side illustrated contact holes 71 and 72 are respectively formed in the case of using the all-binary mask 30 and in the case of using the all-phase shift mask 40.

First, in the case where the contact hole 71 is formed using the binary mask 30, the maximum light intensity increases, but the image log slope (ILS) is lowered, such that it is difficult to concentrate light in a desired area to form a sharp boundary as described above. Accordingly, as illustrated in FIG. 3, a sidewall inclination angle θ1 as defined between an inclined sidewall surface of the contact hole 71 as formed through an insulating layer 68 and a bottom surface of the same insulating layer 68 becomes relatively small and the width of the contact hole 71 at its top portion becomes undesirably large. In general, a contact hole should have a shape more similar to that of a cylinder rather than to that of an inverted cone with an obtuse apex angle so as to increase resolution.

The contact hole 71 of FIG. 3 has a frusto-conical shape with a relatively small sidewall inclination angle θ1 such that a top plan view area of the contact hole 71 is increased, and the ability to form high resolution small diameter contact holes is thereby decreased. Hereinafter, the angle between the inclined sidewall surface and horizontal bottom surface of the insulating layer 68 in the region of the contact hole 71 will also be called its taper angle.

Further, in the case of using the binary mask 30, the insulating layer 68 is not as much etched where the zone of diminishing (non-destructive) light intensity occurs so that there can be a substantially wider top portion of the inverted frusto-conical shape as shown in the left side of FIG. 3, such that the desired cylindrical contact hole (idealized) with a planar top surface is not formed and as such the process margin decreases.

Meanwhile, in the case where the contact hole 71 is formed as illustrated on the right side of FIG. 3 by using the phase shift mask 40, the maximum light intensity is lowered to avoid excessive etch back in areas where the contact hole is not to be formed, and the image log slope (ILS) increases, and thus light can be concentrated in a desired area as previously described. Therefore, the taper angle θ2 in the contact hole 72 formed using the phase shift mask 40 is substantially greater than that (taper angle θ1) of the sidewall of the contact hole 71 formed on the left using the binary mask 30. Although the contact hole 72 formed using the phase shift mask 40 has a shape more similar to an idealized cylinder, and it has a greater taper angle θ2, due to the large amount of destructive interference just outside the upper hole diameter, the use of the phase shift mask 40 increases the likelihood that the portion of the insulating layer 68 immediately surrounding the contact hole 72 will not be as deeply etched back as are farther out areas that are irradiated by not-destructively interfered with light passed through the farther out areas of the transflective unit 42 and a bumped circle 68a may be formed protruding up in the zone of maximum destructive interference. Meanwhile, farther out from the center of the contact hole, because a deeper etch back occurs, elements such as conductive lines disposed on a lower portion of a protective layer may be exposed or otherwise not adequately insulated due to excessive etch back.

More specifically, destructive interference of light occurs in an adjacent area of the light transmitting unit 41 and the transflective unit 42 of the phase shift mask 40, and thus only a small amount of light is incident on the PR layer (not shown) used for forming that portion of the insulating layer 68. Therefore, a protrusion 68a of the insulating layer 68 corresponds to the adjacent area of the light transmitting unit 41 and the transflective unit 42 is created. The protrusion 68a of the insulating layer 68 is formed because there is only very little incident light and the insulating layer 68 is not as deeply etched as it is in other areas. In other words, the insulating layer 68 is not evenly etched back to be completely planar at its top and remains as it is such that the protrusion 68a is formed. If large protrusion 68a is formed around the contact hole 72, the resolution of the process may be reduced.

As described above, in the case where the contact hole is formed using the binary mask 30, the resolution is lowered and the process margin decreases. Further, in the case where the contact hole is formed using the phase shift mask 40, the insulating layer is likely to be over-etched in some areas and under etched (68a) in others.

The present disclosure of invention provides mask that has both binary regions and transflective regions. This provides an exposure mask that is configurable to not only increase patterning resolution and process margin but also to protect the thickness of the insulating layer just beyond the outer boundary of the contact hole so that the thickness of the insulating layer is not excessively reduced by the etch-back effect.

As previously described, whether the resolution increases or not can be ascertained by studying the image log slope (ILS). An effect by which a controlled increase of the ILS is obtained where desired will be discussed below when describing an embodiment in accordance with the present disclosure of invention.

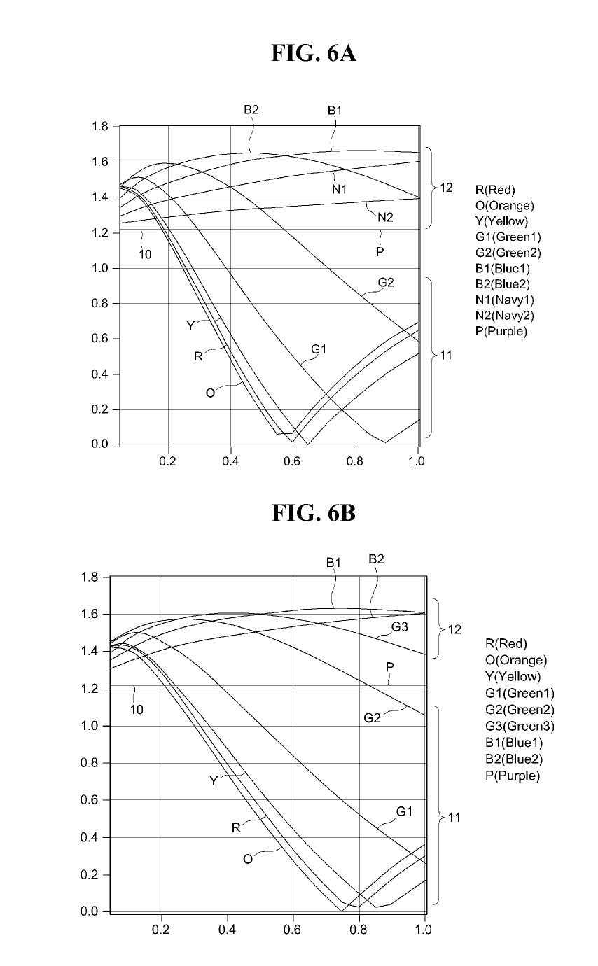

A plurality of mixed binary and phase shift exposure masks in accordance with the present disclosure of invention will be described below with reference to FIGS. 4 to 6.

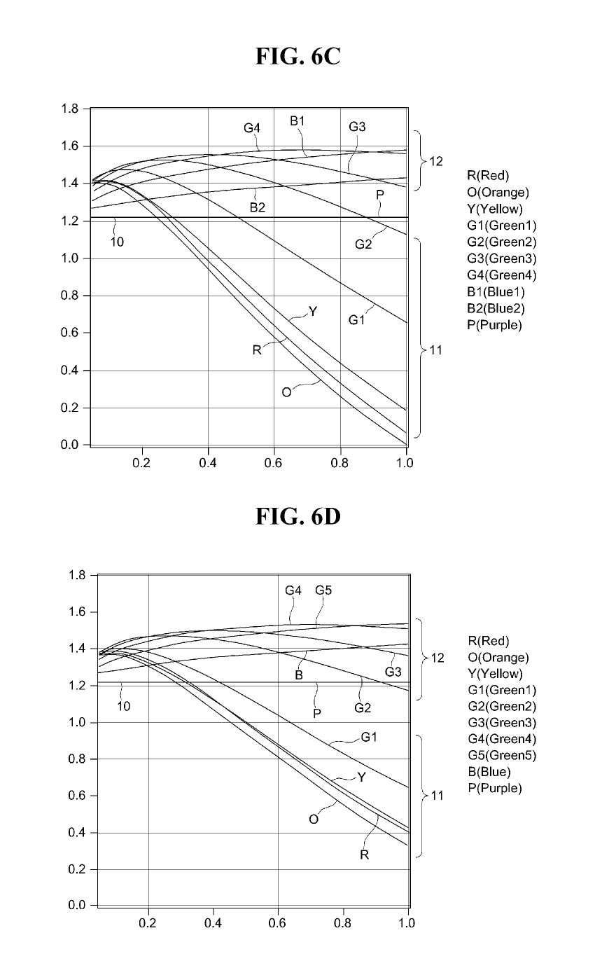

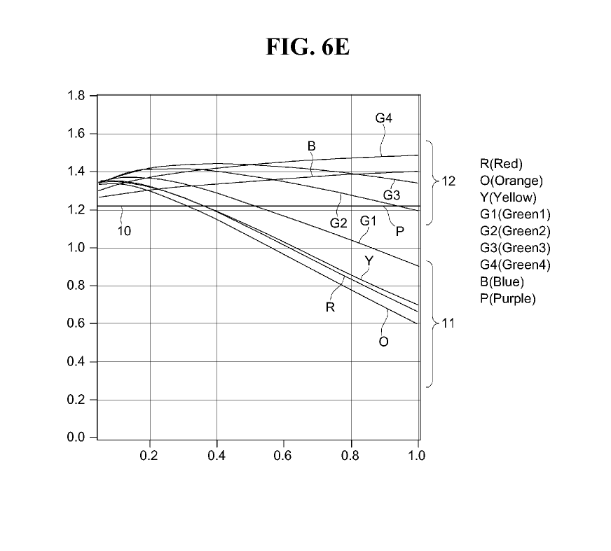

FIGS. 4(a) and 4(b) are respective plan views showing respective and differently configured exposure masks or mask areas with respective thin or thicker inner opaque portions 220 surrounded by transflective portions 230 in accordance with one or more embodiments of the present disclosure of invention. In FIG. 5, the illustrated left and right sides are corresponding cross-sectional views of a display device area and the used lithographic exposure mask(s) that correspond to FIGS. 4(a) and 4(b) respectively. FIGS. 6A through 6E are graphs showing various image log slopes (ILS) that may be developed depending on widths of a first (inner) light blocking unit 220 and a surrounding transflective unit 230.

Referring to FIG. 4 portions (a) and (b), the illustrated exposure mask areas or respective masks 200 each includes a respective full light transmitting unit 210 (e.g., opening), a respective first light blocking unit 220 surrounding the light transmitting unit 210, a respective transflective unit 230 surrounding the first light blocking unit 220, and a respective second light blocking unit 240 surrounding the transflective unit 230.

The light transmitting unit 210 is a transparent pattern configured to let through the maximum intensity of light for forming a through hole (e.g., contact hole), extending through the full thickness of the to be patterned layer (e.g., insulation layer 68) with use of an appropriate photoreactive layer (PR layer). The light transmitting unit 210 may have any of suitable shapes such as a circular shape, a polygonal shape, etc. In other words, the light transmitting unit 210 is an area through which essentially 100% light transmission takes place.

The first light blocking unit 220 surrounds the light transmitting unit 210, and may have different outer boundary and inner boundary shapes depending for example on the outer boundary shape of the light transmitting unit 210. The first light blocking unit 220 is configured to block light, and may include an opaque material such as chromium (Cr) or the like. As comparatively shown in the left and right side representations of FIG. 4, the first light blocking unit 220 may have a shape of a rectangular frame with a constant frame width that is relatively small (e.g., width a1) or relatively big (e.g., width b1). In one class of embodiments the frame width is in the range of about 0.1 μm to about 1 μm. Of course the frame width of the first light blocking unit 220 need not be constant and/or its shape need not be a rectangular one and/or the first light blocking unit 220 need not fully surround the light transmitting unit 210, where each of these variations depends on design objectives in view of the below further details.

In the example of FIG. 4, the transflective unit 230 surrounds the first light blocking unit 220, and may have different outer boundary and inner boundary shapes depending for example on the outer boundary shape of the first light blocking unit 220. The transflective unit 230 is an area which lithography equipment sourced light (e.g., UV and/or near UV wavelengths) is only partly transmitted therethrough and undergoes a phase shift. For example it can transmit light in a range of 1% to 10% of an exposure dose of the incident light. The transflective unit 230 may be made of one or more of suitable phase shifting materials such as MoSiN, MoSiON, MoSiCN, MoSiO, or MoSiCON or other by combination of one or more kinds selected from nitrogen (N), oxygen (O), and carbon (C) and based on molybdenum silicide (MoSi). The transflective unit 230 may have a shape of a rectangular frame with a constant frame width that is relatively small (e.g., width b2) or relatively big (e.g., width a2). In one class of embodiments the frame width is in the range of about 0.1 μm to about 5 μm. Of course the frame width of the transflective unit 230 need not be constant and/or its shape need not be a rectangular one and/or the transflective unit 230 need not fully surround the first light blocking unit 220, where each of these variations depends on design objectives in view of the below further details.

Contact holes 73 and 74 formed using the exposure mask 200 according to an embodiment of the present disclosure will now be described in greater detail with reference to FIG. 5 as well as FIGS. 6A to 6E. Briefly with regard to FIG. 5, the frame width of the first light blocking unit 220 may be used to vary a separation distance between the otherwise adjacent and out-of-phase light rays output from the light transmitting unit 210 and from the transflective unit 230. Additionally, the second light blocking unit 240 functions to assure that excessive etch back does not occur into the thickness of the material layer (e.g., insulation 68) through which the through hole (e.g., contact hole) is formed.

Referring now to FIGS. 6A to 6E, these show how to change ILS values by varying the respective frame widths of the first light blocking unit 220 and of the transflective unit 230, and by varying the transmittance of the phase shifting material.

FIGS. 6A to 6E show graphs of the respective image log slopes (ILS). The Y axis indicates ILS values, where a slope of near zero (0.0) indicates a minimum transmittance state (e.g., due to maximum destructive interference). On the other hand, the horizontal or X axis of the ILS plots of FIGS. 6A to 6E indicates a normalized transmittance in the area of the utilized phase shifting material, where 1.0 is the normalized maximum transmittance through the light transmitting unit 210. The normalized transmittance in the area of the utilized phase shifting material can vary as a function of different phase shifting materials and their respective thicknesses. Although shown in black and white, the graph curves may be color-coded so as to be more easily categorized by eye according to color where the assigned color classifies the curve according to a corresponding frame width of its transflective unit 230. An R (red) graph curve is the case where the transflective unit 230 has a width of 4 μm-5 μm, an O (orange) graph curve is the case where the transflective unit 230 has a width of 3 μm -4 μm, a Y (yellow) graph curve is the case where the transflective unit 230 has a width of 2.4 μm-3 μm, a G (green) graph curve is the case where the transflective unit 230 has a width of 1.0 μm-2.4 μm, a B (blue) graph curve is the case where the transflective unit 230 has a width of 0.6 μm-1.0 μm, an N (navy) graph curve is the case where the transflective unit 230 has a width of 0.2 μm-0.6 μm, and a P (purple) graph curve is the case where the transflective unit 230 has a width of 0.01 μm-0.2 μm.

For instance, in the case of FIG. 6B, the R (red) graph curve is the case where the transflective unit 230 has a width of 4.2 μm, the O (orange) graph curve is the case where the transflective unit 230 has a width of 3.5 μm, the Y (yellow) graph curve is the case where the transflective unit 230 has a width of 2.6 μm, the G1 (green) graph curve is the case where the transflective unit 230 has a width of 2.2 μm, the G2 (green) graph curve is the case where the transflective unit 230 has a width of 1.2 μm, the G3 (green) graph curve is the case where the transflective unit 230 has a width of 1.0 μm, the B1 (blue) graph curve is the case where the transflective unit 230 has a width of 0.6 μm, the B2 (blue) graph curve is the case where the transflective unit 230 has a width of 0.8 μm, and the P (purple) graph curve is the case where the transflective unit 230 has a width of 0.01 μm.

In the case of FIG. 6C, the R (red) graph curve is the case where the transflective unit 230 has a width of 4.2 μm, the O (orange) graph curve is the case where the transflective unit 230 has a width of 3.5 μm, the Y (yellow) graph curve is the case where the transflective unit 230 has a width of 2.6 μm, the G1 (green) graph curve is the case where the transflective unit 230 has a width of 2.2 μm, the G2 (green) graph curve is the case where the transflective unit 230 has a width of 1.4 μm, the G3 (green) graph curve is the case where the transflective unit 230 has a width of 1.2 μm, the G4 (green) graph curve is the case where the transflective unit 230 has a width of 1.0 μm, the B1 (blue) graph curve is the case where the transflective unit 230 has a width of 0.6 μm, the B2 (blue) graph curve is the case where the transflective unit 230 has a width of 0.8 μm, and the P (purple) graph curve is the case where the transflective unit 230 has a width of 0.01 μm.

In the case of FIG. 6D, the R (red) graph curve is the case where the transflective unit 230 has a width of 4.2 μm, the O (orange) graph curve is the case where the transflective unit 230 has a width of 3.5 μm, the Y (yellow) graph curve is the case where the transflective unit 230 has a width of 2.6 μm, the G1 (green) graph curve is the case where the transflective unit 230 has a width of 2.2 μm, the G2 (green) graph curve is the case where the transflective unit 230 has a width of 1.6 μm, the G3 (green) graph curve is the case where the transflective unit 230 has a width of 1.4 μm, the G4 (green) graph curve is the case where the transflective unit 230 has a width of 1.2 μm, the G5 (green) graph curve is the case where the transflective unit 230 has a width of 1.0 μm, the B (blue) graph curve is the case where the transflective unit 230 has a width of 0.6 μm, and the P (purple) graph curve is the case where the transflective unit 230 has a width of 0.01 μm.

In the case of FIG. 6E, the R (red) graph curve is the case where the transflective unit 230 has a width of 4.2 μm, the O (orange) graph curve is the case where the transflective unit 230 has a width of3.5 μm, the Y (yellow) graph curve is the case where the transflective unit 230 has a width of 2.6 μm, the G1 (green) graph curve is the case where the transflective unit 230 has a width of 2.2 μm, the G2 (green) graph curve is the case where the transflective unit 230 has a width of 1.8 μm, the G3 (green) graph curve is the case where the transflective unit 230 has a width of 1.4 μm, the G4 (green) graph curve is the case where the transflective unit 230 has a width of 1.2 μm, the B (blue) graph curve is the case where the transflective unit 230 has a width of 0.6 μm, and the P (purple) graph curve is the case where the transflective unit 230 has a width of 0.01 μm.

FIG. 6A shows the case where the first light blocking unit 220 has a width of 0 μm, FIG. 6B shows the case where the first light blocking unit 220 has a width of 0.2 μm, FIG. 6C shows the case where the first light blocking unit 220 has a width of 0.4 μm, FIG. 6D shows the case where the first light blocking unit 220 has a width of 0.6 μm, and FIG. 6E shows the case where the first light blocking unit 220 has a width of 0.8 μm. That is, FIG. 6A shows ILS values resulting from being applied with a phase shift mask that has no first light blocking unit 220. On the other hand, FIGS. 6B to 6E show ILS values resulting from being applied with exposure masks that do have a first light blocking unit 220 according to various embodiments of the present disclosure of invention.

Further, the graph identified as curve 10 represents the case where the ILS is 1.2, and it is a reference value in terms of light quality. That is, if the ILS value measures 1.2 or more regardless of the normalized transmittance of the utilized phase shifting material (X axis), resolution can be considered as increasing above the reference value (Y axis value=1.2).

Referring to FIGS. 6A to 6E, an optimum length ratio of the first light blocking unit 220 to the transflective unit 230 will be discussed below.

In the case of FIG. 6B, it is preferable for the first light blocking unit 220 and the transflective unit 230 to have a ratio of respective frame widths in the range of 1:0.9 to 1:5. In other words, when the first light blocking unit 220 has a width of 0.2 μm, and the transflective unit 230 has a width of 0.2 μm to 1 μm, the ILS value is improved to be 1.2 or more.

In the case of FIG. 6C, it is preferable for the first light blocking unit 220 and the transflective unit 230 to have a width ratio of 1:0.5 to 1:3.5. In other words, when the first light blocking unit 220 has a width of 0.4 μm, and the transflective unit 230 has a width of 0.2 μm to 1.4 μm, the ILS value is improved to be 1.2 or more.

In the case of FIG. 6D, it is preferable for the first light blocking unit 220 and the transflective unit 230 to have a width ratio of 1:0.33 to 1:2.66. In other words, when the first light blocking unit 220 has a width of 0.6 μm, and the transflective unit 230 has a width of 0.2 μm to 1.6 μm, the ILS value is improved to be 1.2 or more.

In the case of FIG. 6E, it is preferable for the first light blocking unit 220 and the transflective unit 230 to have a width ratio of 1:0.25 to 1:2.25. In other words, when the first light blocking unit 220 has a width of 0.8 μm, and the transflective unit 230 has a width of 0.2 μm to 1.8 μm, the ILS value is improved to be 1.2 or more.

After referring to FIGS. 6B to 6E showing all the results of experiments conducted by changing the frame widths of the first light blocking unit 220 and of the transflective unit 230, it has been deemed preferable for the first light blocking unit 220 and the transflective unit 230 to have a width ratio of 1:0.9 to 1:2.25 regardless of the transmittance of the phase shifting material (regardless of the corresponding X-axis value).

Each region of the exposure mask 200 is disposed on a substrate to correspond to the contact holes 73 and 74, and then the improved contact holes 73 and 74 according to various embodiments in accordance with the present disclosure of invention will be described below with reference to FIGS. 5 and 6B to 6E.

In terms of the ILS, as the width of the first light blocking unit 220 becomes larger, all ILS values increase, regardless of the transmittance of the phase shifting material. In the case of the graphs of FIG. 6A where the phase shift mask without the first light blocking unit 220 is applied, curves 11 are the cases where the transflective unit 230 has a width of 1 μm to 5 μm, and curves 12 are the cases where the transflective unit 230 has a width of 0.1 μm to 0.8 μm. In the absence of the first light blocking unit 220, the transflective unit 230 having a very fine width is applied to the exposure mask 200 so that the ILS value increases. However, in the case of the graphs of FIGS. 6B-6E, as the width of the first light blocking unit 220 becomes larger, graph curves having the ILS value of 1.2 or more increase regardless of the transmittance of the phase shifting material and the width of the transflective unit 230.

In other words, the exposure mask with improved ILS values may be manufactured by properly selecting modes of operation in accordance with the graph curve values where the graph curve portions (segments) occur only above the reference graph curve corresponding to curve 10 in graphs 6B to 6E. As previously discussed, the first light blocking unit 220 and the transflective unit 230 are adjusted to have a width ratio of 1:1 to 1:2.25 so that the ILS can be improved.

The first light blocking unit 220 and the transflective unit 230 may have different widths from each other. The first light blocking unit 220 may have a larger width than the transflective unit 230. On the contrary, the transflective unit 230 may have a larger width than the first light blocking unit 220. The difference between the widths of the first light blocking unit 220 and the transflective unit 230 may be appropriately determined depending on the area of the contact hole.

According to various embodiments in accordance with of the present disclosure of invention, the ILS is improved when compared to the case where only the phase shift mask is applied, and thus light of more increased exposure dose is concentrated in a fine area. Therefore, defects (e.g., excessive etch back) in areas in which the contact holes 73 and 74 are not intended to be formed are reduced so that the mass production process margin is thereby improved.

With respect to the issue of excessive etch back of the insulating layer 68 where the contact hole is not intended to be formed, the insulating layer 68 is not excessively etched back or hardly etched at all according to some embodiments of the present disclosure, this being compared to the case where only an all phase shift mask is used. That is, in the phase shift mask, the transflective unit is disposed on the insulating layer 68, and thus some light of the exposure dose reaches the insulating layer 68. The partly exposed insulating layer 68 is partially etched in a developing process as illustrated in FIG. 3. According to an embodiment of the present disclosure, the transflective unit 230 of the exposure mask 200 is disposed only in an area corresponding to a region near where the contact holes 73 and 74 may be formed. In the residual area, light is blocked by the second light blocking unit 240. Therefore, the light does not reach the insulating layer 68 so that the insulating layer 68 is not etched back. Further, the insulating layer 68 does not have the protrusion 68a shown in FIG. 3 because of being under-etched due to destructive light interference.

As previously described, the ILS is improved so that the insulating layer 68 has an increased sidewall taper angle in the contact holes 73 and 74. Accordingly, the contact holes 73 and 74 are of finer resolution as opposed to having widely spread out top diameters. For instance, the insulating layer 68 may have a relatively steep sidewall taper angle of about 60 degrees to about 90 degrees in the contact holes 73 and 74.

Thus, the ILS and the taper angle of the contact holes are improved, and the insulating layer is not excessively etched back, thereby improving the whole process margin.

A configuration of a display device will be described below with reference to FIG. 5.

Referring to FIG. 5, a gate line (not shown) and a gate electrode 61 are disposed on a display substrate 20 made of glass, plastic, or the like. The gate line includes a plurality of gate electrodes 61 protruding from the gate line and a gate pad (not shown) corresponding to an end portion having a large area for connection to a different layer or an external drive circuit.

A gate insulating layer 62 made of a silicon nitride (SiNx) or a silicon oxide (SiOx) is disposed on the gate line (not shown) and the gate electrode 61.

A plurality of semiconductive islands 63 made for example of hydrogenated amorphous silicon (a-Si stands for amorphous silicon), polysilicon, or the like are disposed on the gate insulating layer 62. The semiconductive islands 63 mainly extend in a longitudinal direction, and includes a plurality of projections (not shown) extending toward the gate electrode 61.

The plurality of semiconductive islands 63 may instead be a semiconductive oxide. The semiconductive oxide may include at least one selected from the group consisting of a zinc (Zn), gallium (Ga), indium (In), and tin (Sn) oxide.

For example, the oxide semiconductor may be made of an oxide based on zinc (Zn), gallium (Ga), tin (Sn), or indium (In), or an oxide semiconductor material, such as zinc oxide (ZnO), indium-gallium-zinc oxide (InGaZnO₄), Indium-zinc oxide (In—Zn—O), and zinc-tin oxide (Zn—Sn—O), which are complex oxides.

In detail, the semiconductive oxide may include an IGZO-based oxide consisting of indium (In), gallium (Ga), zinc (Zn) and oxygen (O). In addition, the oxide semiconductor may include In—Sn—Zn—O-based metal oxide, In—Al—Zn—O-based metal oxide, Sn—Ga—Zn—O-based metal oxide, Al—Ga—Zn—O-based metal oxide, Sn—Al—Zn—O-based metal oxide, In—Zn—O-based metal oxide, Sn—Zn—O-based metal oxide, Al—Zn—O-based metal oxide, In—O-based metal oxide, Sn—O-based metal oxide, and Zn—O-based metal oxide.

A plurality of ohmic contacts 64 and 65 are formed on the semiconductor 63, and are configured to reduce contact resistance. The ohmic contacts 64 and 65 may be made of a material such as n+ hydrogenated amorphous silicon which is doped with n-type impurities such as phosphorus (P) at a high concentration, or may be made of silicide.

A plurality of data lines (not shown) and a plurality of drain electrodes 67 are formed on the ohmic contacts 64 and 65 and the gate insulating layer 62.

Each data line (not shown) includes a plurality of source electrodes 66 extending toward the gate electrode 61, and a data pad (not shown) corresponding to an end portion having a wide area for connection to a different layer or an external driver circuit.

The drain electrode 67 is separated from the data line (not shown), and faces the source electrode 66 with respect to the gate electrode 61.

In detail, the source electrode 66, the drain electrode 67, and the data line (not shown) may be made of a refractory metal such as molybdenum, chromium, tantalum and titanium, or alloys thereof, and may have a multilayer structure that includes a refractory metal layer and low resistance conductive layer. The multilayer structure may include, for example, a double layer consisting of a chromium or molybdenum (an alloy thereof) lower layer and an aluminum (an alloy thereof) upper layer, and a triple layer consisting of a molybdenum (an alloy thereof) lower layer, an aluminum (an alloy thereof) intermediate layer, and a molybdenum (an alloy thereof) upper layer.

One gate electrode 61, one source electrode 66, and one drain electrode 67 compose one thin film transistor (TFT), together with the projection (not shown) of the semiconductor 63, and a channel of the TFT is formed at the projection between the source electrode 66 and drain electrode 67.

A passivation layer 68 is formed on the gate line (not shown), the data line (not shown), the source electrode 66, the drain electrode 67, and an exposed part of the semiconductor 63. The passivation layer 68 is made of an inorganic insulating material such as a silicon nitride (SiNx) or a silicon oxide (SiOx), or of an acrylic organic compound having a small dielectric constant, or of an organic insulating material such as benzocyclobutene (BCB) or perfluorocyclobutane (PFCB), or is formed to be planarized in a laminated structure including the inorganic and organic insulating materials using a deposition method such as plasma enhanced chemical vapor deposition (PECVD).

The passivation layer 68 has a plurality of drain contact holes 73 and/or 74 to expose the respective drain electrodes 67, respectively, a plurality of gate pad contact holes (not shown) to expose the respective gate pads (not shown), respectively, and a plurality of data pad contact holes (not shown) to expose the respective data pads (not shown), respectively.

A plurality of pixel electrodes (not shown) are formed on the passivation layer 68. The pixel electrode may be made of a transparent conductive material such as ITO or IZO, or a reflective metal such as aluminum, silver, or alloys thereof.

The pixel electrode (not shown) is physically and electrically connected to the drain electrode 67 through the contact holes 73 and 74, and receives data voltage from the drain electrode 67. An electric field is generated by the pixel electrode (not shown), to which the data voltage is applied, and a common electrode (not shown) of a different display substrate (not shown) to which common voltage is applied, thereby determining an orientation of liquid crystal molecules of a liquid crystal layer (not shown) between the two electrodes. The pixel electrode and the common electrode define a capacitor (hereinafter referred to as a “liquid crystal capacitor”) to maintain the applied voltage after a thin film transistor is turned off.

Meanwhile, in the case where embodiments of the present disclosure of invention are used and relate instead to an organic light emitting diode display (OLED), the organic light emitting diode display may include an organic light emitting layer (not shown) on the pixel electrode (not shown) and an opposite electrode (not shown) disposed on the organic light emitting layer.

The pixel electrode (not shown) is disposed to correspond to an opening of a pixel defining layer (not shown), but it is not necessarily disposed in the opening of the pixel defining layer. The pixel electrode may be disposed under the pixel defining layer so that a portion of the pixel electrode may overlap the pixel defining layer. The pixel defining layer may be made of a polyacrylate resin, polyimide resin, silica-based inorganic material, or the like.

The organic light emitting layer (not shown) is formed on the pixel electrode, and the opposite electrode (not shown) serving as a cathode is formed on the organic light emitting layer. As described above, the organic light emitting diode display is formed by including the pixel electrode, the organic light emitting layer, and the opposite electrode.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings.

What is claimed is:

1. A display device comprising:
a substrate;
a gate line and a data line disposed on the substrate;
a thin film transistor disposed on the substrate, the thin film transistor being connected to the gate line and the data line;
a pixel electrode connected to the thin film transistor; and
an insulating layer disposed on the substrate,
wherein the insulating layer has a contact hole extending therethrough and a bottom portion of the contact hole has a sidewall taper angle of about 60° to about 90°, where a 90° sidewall taper angle corresponds to a sidewall portion having maximum steepness.

2. The display device of claim 1, wherein the insulating layer is configured to cover at least one of a semiconductive layer, a drain electrode, a gate line, a data line, and a pad electrode.

3. The display device of claim 1, wherein any one or more of a semiconductive layer, a drain electrode, a gate line, a data line, and a pad electrode is exposed by a respective contact hole having a sidewall taper angle of about 60° to about 90°.

4. A lithographic exposure mask comprising:
a light transmitting unit;
a first light blocking unit surrounding the light transmitting unit;
a transflective unit surrounding the first light blocking unit; and
a second light blocking unit surrounding the transflective unit.

5. The exposure mask of claim 4, wherein the first light blocking unit and the transflective unit have respective frame shapes of different respective frame widths from each other.

6. The exposure mask of claim 4, wherein the light transmitting unit has a circular or polygonal shape.

7. The exposure mask of claim 4, wherein the light transmitting unit is a pattern configured to form a contact hole.

8. The exposure mask of claim 4, wherein the width ratio of the first light blocking unit to the transflective unit is 1:0.9 to 1:2.25.

9. The exposure mask of claim 8, wherein the first light blocking unit has a width of about 0.1 μm to about 1 μm.

10. The exposure mask of claim 8, wherein the transflective unit has a width of about 0.1 μm to about 5 μm.

11. A method for manufacturing a display device, the method comprising:
forming an insulating layer on a substrate;
exposing the insulating layer to light using an exposure mask; and
forming a contact hole by developing the light-exposed insulating layer using a positive development method,
wherein the used exposure mask comprises:
a light transmitting unit;
a first light blocking unit surrounding the light transmitting unit;
a transflective unit surrounding the first light blocking unit; and
a second light blocking unit surrounding the transflective unit.

12. The method of claim 11, wherein the first light blocking unit and the transflective unit have different widths from each other.

13. The method of claim 11, wherein the light transmitting unit, the first light blocking unit, and the transflective unit are formed on an area where the contact hole is formed.

14. The method of claim 11, wherein the insulating layer has a taper angle of about 60° to about 90° in the contact hole.

15. The method of claim 11, wherein the light transmitting unit has a circular or polygonal shape.

16. The method of claim 11, wherein the light transmitting unit is a pattern configured to form a contact hole.

17. The method of claim 11, wherein the width ratio of the first light blocking unit to the transflective unit is 1:0.9 to 1:2.25.

18. The method of claim 17, wherein the first light blocking unit has a width of about 0.1 μm to about 1 μm.

19. The method of claim 17, wherein the transflective unit has a width of about 0.1 μm to about 5 μm.
